(19) United States
(12) Patent Application Publication
(10) Pub. No.: US 2009/0072798 A1
(43) Pub. Date: Mar. 19, 2009

(54) APPARATUS AND METHOD FOR APPLYING HIGH VOLTAGE WITH HIGH FREQUENCY

(75) Inventors: Jeongje PARK, Hawseong-si (KR); Kyungil CHO, Seoul (KR); Jaechan PARK, Yongin-si (KR); WANTAEK Han, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/048,366

(22) Filed: Mar. 14, 2008

(30) Foreign Application Priority Data
Sep. 14, 2007 (KR) 10-2007-0093463
Dec. 6, 2007 (KR) 10-2007-0126207

(51) Int. Cl. G05F 1/24; H03H 7/40

(52) U.S. Cl. 323/247; 333/17.3

(57) ABSTRACT

An apparatus and a method for applying high voltage with high frequency. The apparatus includes a power generator for generating electric power with predetermined frequency, a voltage transformer receiving the electric power generated by the power generator, amplifying voltage of the electric power received, and applying the amplified voltage to a load, and an impedance matcher connected between the power generator and the voltage transformer to match impedances of the power generator and the voltage transformer to thereby transmit the electric power to the voltage transformer. High voltage with high frequency is obtained by transmitting the electric power generated from the power generator to the load without reflecting loss while conducting an impedance matching, and amplifying the voltage applied to the load using the coupled inductor and LC resonance.

### BACKGROUND OF THE INVENTION

1. Field of the Invention

The present invention relates to an apparatus and & method for applying high voltage with high frequency, and more particularly to an apparatus and a method for applying high voltage with high frequency which transmit, to a load, high frequency power generated from a power generator with impedance matching, and amplify voltage applied to the load upon power transmission using a coupled inductor and LC resonance, and keep the impedance of the load side constant irrespective of type, dimension and capacity of the load to generate LC resonance.

2. Description of the Prior Art

As one of the methods for keeping foods fresh, there is a method of applying high voltage with high frequency to the foods for preserving them for a long time without freezing the same. Ms is a method which rotates water contained in foods using high voltage with the frequency belonging to a rotating motion range of water molecules to lower the freezing point of the foods, thereby preserving them below zero without freezing. For preservation of the foods using such a method, the foods should be applied with high voltage above 1 kV with high frequency between 250 kHz and 1 GHz. Thus, it needs an apparatus for generating high voltage with high frequency and applying the same to foods.

An exemplary apparatus for applying high power with high frequency that is currently available generates electric power through a power generator, amplifies the electric power with a power amplifier thereby to obtain high electric power, transmits the amplified electric power to the load while performing impedance matching with an impedance matcher.

The impedance of the load side becomes different from an initial value dependant on the existence of load, and type, dimension and capacity of the load, and such a difference between the impedances makes the preset impedance matching deviate.

Here, the impedance matching means to make impedances of the power supply and the load identical to each other to prevent reflection loss upon circuit connection. Generally, the impedance matching is obtained by unifying both the impedances of the power supply and the load into 50 ohms.

### SUMMARY OF THE INVENTION

The present invention has been made to solve the problems occurring in the prior art, and an object of the present invention is to provide an apparatus and a method for applying high voltage with high frequency which efficiently transmit it to a load without reflecting loss irrespective of type, dimension, and capacity of the load and amplify the voltage applied to the load to obtain the high voltage with high frequency as well.

In accordance with an aspect of the present invention, there is provided an apparatus for applying high voltage with high frequency comprising: a power generator for generating electric power with predetermined frequency; a voltage transformer receiving the electric power generated by the power generator, amplifying voltage of the electric power received, and applying the amplified voltage to a load; and an impedance matcher connected between the power generator and the voltage transformer to match impedances of the power generator and the voltage transformer to thereby transmit the electric power to the voltage transformer.

In accordance with another aspect of the present invention, there is provided a method of applying high voltage with high frequency comprising the steps of: generating electric power with predetermined frequency using a power generator; transmitting the electric power while conducting an impedance-matching with the power generator; and applying, to a load, the voltage of the electric power transmitted from the above step while amplifying the voltage.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram illustrating a first exemplary embodiment of a structure of an apparatus for applying high voltage with high frequency according to one present invention;

FIG. 2 is a flow chart illustrating a first exemplary embodiment of a procedure of a method of applying high voltage with high frequency according to the present invention;

FIG. 3 is a circuit diagram illustrating the circuit structure of a voltage transformer included in the first exemplary embodiment of an apparatus for applying high voltage with high frequency according to the present invention;

FIG. 4 is a block diagram illustrating a second exemplary embodiment of a structure of an apparatus for applying high voltage with high frequency according to the present invention;

FIG. 5 is a flow chart illustrating a second exemplary embodiment of a procedure of a method of applying high voltage with high frequency according to the present invention; and

FIG. 6 is a circuit diagram illustrating the structure of a voltage transformer included in the second exemplary embodiment of an apparatus for applying high voltage with high frequency according to the present invention.

### DETAILED DESCRIPTION OF THE EXEMPLARY EMBODIMENTS

Hereinafter, exemplary embodiments of the present invention will be described with reference to the accompanying drawings.

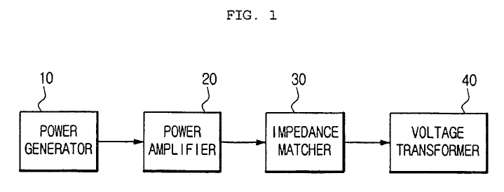

FIG. 1 is a block diagram illustrating a first exemplary embodiment of a structure of an apparatus for applying high voltage with high frequency according to the present invention.

Referring to FIG. 1, the apparatus for applying high voltage with high frequency includes a power generator 10, a power amplifier 20, an impedance matcher 30, and a voltage transformer 40.

The power generator 10 is a device for generating electric power with predetermined frequency between 250 kHz and 1 GHz, preferably. In an embodiment, the electric power generated by the power generator 10 is transmitted to the power amplifier 20. The power amplifier 20 is a device for amplifying the electric power generated by the power generator 10. In an embodiment, the power amplifier amplifies the electric power from the power generator to 100 W or more, preferably.

The impedance matcher 30 is connected between the power amplifier 20 and the voltage transformer 40 to make the impedances of a power source side and a load side identical to each Other for impedance matching. In an embodiment, the impedance matcher 30 carries out the impedance matching without a voltage drop through a circuit in which one or more resistors, one or more inductors, and one or more capacitors are connected in parallel.

The voltage transformer 40 amplifies the amplitude of the voltage of the electric power transmitted from the impedance matcher 30, and applies maximum voltage to the load by amplifying the impedance of the load side. In an embodiment, the voltage transformer 40 amplifies the voltage with a coupled inductor, and amplifies the load side impedance with an LC resonance circuit, thereby transmitting maximum voltage to the load.

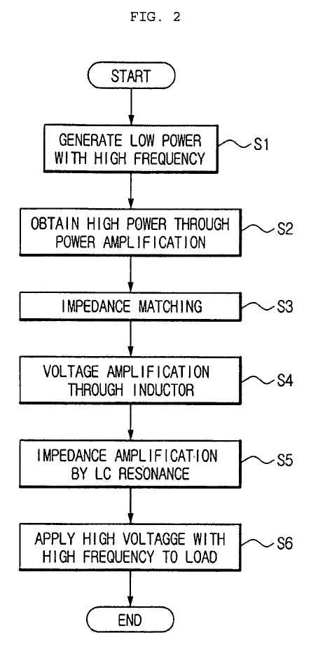

FIG. 2 is a flow chart illustrating an exemplary embodiment of a procedure of a method of applying high voltage with high frequency according to the present invention. Referring to FIG. 2, the method starts with a step S1 of generating electric power with predetermined frequency using the power generator 10. In an embodiment, the power generator 10 generates the electric power with frequency between 250 kHz and 1 GHz.

In an embodiment, the power amplifier 20 amplifies the electric power generated from the power generator 10 to obtain high electric power (S2). The step S2 is carried out by the power amplifier 20 to obtain high electric power if the dimension of the electric power generated from the power generator 10 is not sufficient. In an embodiment, the power amplifier 20 can obtain high electric power of 100 W or more using a power amplifying circuit.

The impedance matcher 30 connected between the power amplifier 20 and the power transformer 40 transmits the electric power without reflecting loss through an impedance matching (S3). That is, the impedance matcher 30 matches the impedances of the power generator 10 and the power amplifier 20, that are the power source side, with the impedance of the load side to thereby prevent reflecting loss upon power transmission.

In an embodiment of the present invention which aims at finally applying high voltage to the load, it is preferable that a voltage drop does not occur in the process of impedance matching by the impedance matcher 30. Thus, in an embodiment, the impedance matcher 30 is configured such that one or more resistors, one or more inductors, and one or more capacitors are connected in parallel so as to prevent the voltage drop.

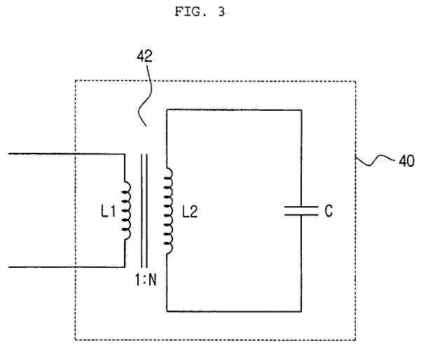

The voltage transformer 40 receives the electric power from the impedance matcher 30 and applies it to the load. In an embodiment, the voltage transformer 40 amplifies the voltage of the electric power received using a coupled inductor, and resonates a secondary inductor of the coupled inductor with a capacitor to amplify the impedance of the secondary side of the coupled inductor, thereby maximizing the voltage applied to the secondary side (S4 and S5). This will be described in detail with reference to FIG. 3.

FIG. 3 is a circuit diagram illustrating the circuit construction of the voltage transformer 40 included in the first embodiment of the present invention. As illustrated in FIG. 3, the voltage transformer 40 may include a coupled inductor 42 having a primary inductor L1 and a secondary inductor L2, and a capacitor C that is resonated with the secondary inductor L2 of the coupled inductor 42. When, the electric power is transmitted from the impedance matcher 30, the voltage of the electric power transmitted is then transmitted to the primary inductor L1 of the coupled inductor 42. The secondary side impedance of the voltage transformer 40 is amplified according to a winding ratio (1:N) between the primary inductor L1 and the secondary inductor L2, and the voltage applied to the secondary inductor L2 is also amplified by the same ratio (S4).

Further, in order to distribute a voltage to the load side from the amplified voltage as much as possible, the secondary inductor L2 of the coupled inductor 42 and the capacitor C generate an LC resonance therebetween to thereby maximize the secondary side impedance of the coupled inductor 42 (S5). Herein, for resonance, the secondary inductor L2 of the coupled inductor 42 and the capacitor C should satisfy the condition of equation 1 below.

$${Z}_{c} = \frac{1}{jwC} = jwL = {Z}_{L} \qquad Equation 1$$

In the equation 1, Zc is the impedance of the capacitor C, and Z_{L} is the impedance of the secondary inductor L2 of the coupled inductor 42. Also, C is the capacitance of the capacitor C, and L is the inductance of the secondary inductor L2. Further, ω is an angular frequency, which is defined as 2π f where f is the frequency of the electric power generated from the power generator 10. That is, if the impedances of the capacitor C and the secondary inductor L2 of the coupled inductor 42 are identical to each other like in the equation 1, the impedance of the secondary side of the coupled inductor 42 is maximized by an LC resonance.

By impedance amplification by the resonance between the secondary inductor L2 of the coupled inductor 42 and the capacitor C, most of the voltage amplified by the coupled inductor 42 in step S4 is applied to both terminals of the capacitor C to thereby obtain high voltage. Herein, a load is connected between both electrodes of the capacitor C, or otherwise both the electrodes of the capacitor C are used as a final output terminal, so that high voltage with high frequency is applied to the load (S6).

When the first exemplary embodiment of the present invention is used for use in keeping foods fresh, for instance, the foods can be positioned between both the electrodes of the capacitor C. As high voltage with high frequency is applied to the foods between both the electrodes of the capacitor C, the freezing point of the foods is lowered so that the foods can he preserved for a long period without being frozen. This makes it possible to prevent the growth of microbes in the foods and oxidation of the foods and preserve the foods for a long period.

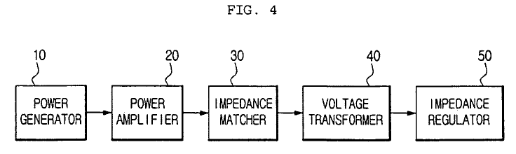

FIG. 4 is a block diagram illustrating a second exemplary embodiment of a structure of an apparatus for applying high voltage with high frequency according to the present invention. Referring to FIG. 4, the second exemplary embodiment of an apparatus for applying high voltage with high frequency includes a power generator 10, a power amplifier 20, an impedance matcher 30, a voltage transformer 40, and an impedance regulator 50. That is, the apparatus further includes the impedance regulator 50 as compared to that of the first exemplary embodiment as illustrated in FIG. 1.

In the second embodiment, since the functions of the power generator 10, the power amplifier 20, and the impedance matcher 30 are identical to those of the first embodiment described with reference to FIG. 1, they can be easily understood by the skilled in the art with reference to the first embodiment so the detailed description thereof will be omitted.

The impedance regulator 50 is a device which is connected to the voltage transformer 40 to thereby regulate the impedance of the voltage transformer 40 to a desired value. The voltage regulator 40 amplifies a voltage with a coupled inductor and an LC resonance circuit, and applies it to a load. Herein, a problem arises in that an LC resonance characteristic of the voltage transformer 40 can be changed due to the load connected to the voltage transformer 40.

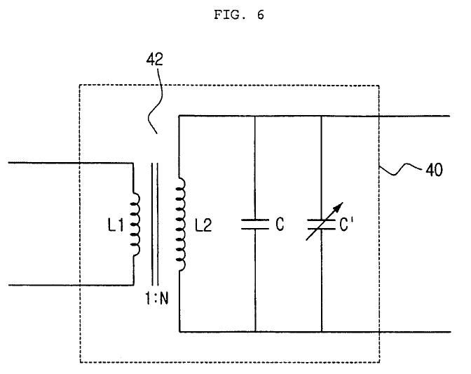

Thus, the impedance regulator 50 measures the impedance of the voltage transformer 40. When the impedance of the voltage transformer 40 is changed as the load is connected thereto, the impedance regulator 50 regulates the sum of the impedances of both the voltage transformer 40 and the load into a predetermined value. Different from the said first embodiment, the voltage transformer 40 further includes a variable capacitor for impedance regulation by the impedance regulator 50, which will be described later referring to FIG. 6.

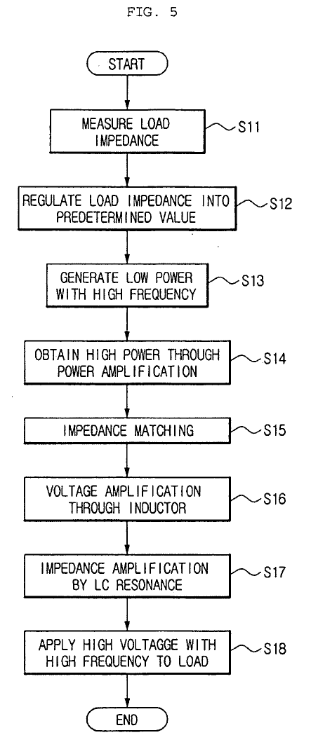

FIG. 5 is a flow chart illustrating a second exemplary embodiment of a procedure of a method of applying high voltage with high frequency according to the present invention. Referring to FIG. 5, the method starts with the step S11 of measuring impedance of a load by the impedance regulator 50.

Then, for impedance matching, the impedance regulator 50 regulates the load side impedance into a predetermined impedance value (S12).

Next, the power generator 10 generates electric power with predetermined frequency (S13). In an embodiment, the power generator 10 generates the electric power with high frequency between 250 kHz and 1 GHz.

In an embodiment, the power amplifier 20 amplifies the electric power generated from the power generator 10 to obtain high electric power (S14). The step S14 is carried out by the power amplifier 20 to obtain high electric power if the dimension of the electric power generated from the power generator 10 is not sufficient. In an embodiment, the power amplifier 20 can obtain high electric power of 100 W or more.

The impedance matcher 30 connected between the power amplifier 20 and the power transformer 40 transmits the electric power without reflecting loss through an impedance matching (S15). That is, the impedance matcher 30 matches the impedances of the power generator 10 and the power amplifier 20, that are the power source side, with the impedance of the load side to thereby prevent reflecting loss upon power transmission.

In an embodiment of the present invention which aims at finally applying high voltage to the load, it is preferable that a voltage drop does not occur in the process of impedance matching by the impedance matcher 30. Thus, in an embodiment, the impedance matcher 30 is configured such that one or more resistors, one or more inductors, and one or more capacitors are connected in parallel so as to prevent the voltage drop.

The voltage transformer 40 receives the electric power from the impedance matcher 30, amplifies the voltage thereof, and applies it to the load. This process will be described with reference to FIG. 6.

FIG. 6 is a circuit diagram illustrating the circuit construction of the voltage transformer 40 included in the second exemplary embodiment of the present invention. As illustrated in FIG. 6, the voltage transformer 40 may include a coupled inductor 42 having a primary inductor L1 and a secondary inductor L2, a capacitor C, and a variable capacitor C′.

When the electric power is transmitted from the impedance matcher 30, the voltage of the electric power transmitted is first transmitted to the primary inductor L1 of the coupled inductor 42. The secondary side impedance of the voltage transformer 40 is amplified according to a winding ratio (1:N) between the primary inductor L1 and the secondary inductor L2, and the voltage applied to the secondary inductor L2 is also amplified by the same ratio (S16).

In order to distribute the voltage to the load side from the amplified voltage as much as possible, the secondary inductor L2 of the coupled inductor 42 maximizes the secondary side impedance of the coupled inductor 42 through an LC resonance. However, if a load, e.g., an object such as foods, is positioned between both electrodes of the capacitor C connected to the secondary side of the inductor 42, the impedance of the capacitor C is varied. Then, a problem occurs in that an LC resonance characteristic is changed.

Accordingly, in the second exemplary embodiment as illustrated in FIG. 6, the voltage transformer 40 includes the variable capacitor C′ connected in parallel to the capacitor C. Referring also to FIGS. 4 and 6, the impedance regulator 50 is connected in parallel to the variable capacitor C′ of the voltage transformer 40. In the steps S11 and S12, the impedance regulator 50 measures the impedance of a load connected to the voltage transformer 40. If the impedance of the voltage transformer 40 is varied due to the load, the impedance regulator 50 regulates the impedance of the variable capacitor C′ so that the sum of both the impedances of the load and the voltage transformer 40 is maintained to a predetermined value.

If it is, for instance, denoted that capacitance of a capacitor C is C, capacitance of a variable capacitor C′ is C′, total capacitance of a circuit, in which the capacitor C and the variable capacitor C′ are connected, is Cₜₒₜₐₗ, Cₜₒₜₐₗ is calculated by equation 2 below.

Cₜₒₜₐₗ=C+C′ Equation 2

Herein, when a load is connected to a capacitor C, capacitance of the capacitor C is varied. In this case, the impedance regulator 50 regulates the capacitance of the variable capacitor C′ to thereby keep Cₜₒₜₐₗ constant.

Meanwhile, in order for the voltage transformer 40 to generate an LC resonance, the secondary inductor L2 of the coupled inductor 42 should satisfy the condition of equation 3 below.

$${Z}_{c} = \frac{1}{{jwC}_{total}} = jwL = {Z}_{L} \qquad Equation 3$$

In the equation 3, Zc is the impedance of a circuit in which the capacitor C and the variable capacitor C′ are connected in parallel, and Z_{L} is the impedance of the secondary inductor L2 of the coupled inductor 42. Also, ω is an angular frequency, which is defined as 2π f where f is the frequency of the electric power generated from the power generator 10.

That is, if the sum of the impedances of both the capacitor C and the variable capacitor C′ is identical to that of the secondary inductor L2 of the coupled inductor 42 like in the equation 3, the impedance of the secondary side of the coupled inductor 42 is maximized by an LC resonance (S17).

By impedance amplification by the resonance between the secondary inductor L2 of the coupled inductor 42 and the capacitor C and the variable capacitor C′, most of voltage amplified by the coupled inductor 42 in step S16 is applied to both terminals of the capacitor C to thereby obtain high voltage. Herein, a load is connected between both electrodes of the capacitor C, or otherwise both the electrodes of the capacitor C are used as a final output terminal, so that high voltage with high frequency is applied to the load (S18).

When the second exemplary embodiment according to the present invention is, for instance, used for keeping foods fresh, the foods can be positioned between both the electrodes of the capacitor C. As high voltage with high frequency is applied to the foods between both the electrodes of the capacitor C, the freezing point of the foods is lowered so that the foods can be preserved for a long period without being frozen. This makes it possible to prevent the growth of microbes in the foods and oxidation of the foods and preserve the foods for a long period. Further, since the variable capacitor C′ regulates the impedance of the voltage transformer 40, an LC resonance can be generated irrespective of type, dimension and amount of the foods positioned between the capacitors C.

As set forth before, according to the apparatus and method for applying high voltage with high frequency, high frequency power generated from the power generator is transmitted to the load through an impedance matching, and voltage applied to the load upon power transmission is amplified using the coupled inductor and LC resonance, thereby keeping the impedance of the load side constant irrespective of type, dimension and capacity of the load and generating LC resonance.

Although exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. An apparatus for applying high voltage with high frequency comprising:
a power generator for generating electric power with predetermined frequency;
a voltage transformer receiving the electric power generated by the power generator, amplifying voltage of the electric power received, and applying the amplified voltage to a load; and
an impedance matcher connected between the power generator and the voltage transformer to match impedances of the power generator and the voltage transformer to thereby transmit the electric power to the voltage transformer.

2. The apparatus for applying high voltage with high frequency according to claim 1, wherein the voltage transformer comprises:
a coupled inductor having a primary inductor and a secondary inductor, wherein the primary inductor is connected in parallel with the impedance matcher; and
a capacitor connected in parallel with the secondary inductor of the coupled inductor to resonate with the secondary inductor of the coupled inductor.

3. The apparatus for applying high voltage with high frequency according to claim 2, wherein the impedance of the secondary inductor of the coupled inductor is identical to the impedance of the capacitor.

4. The apparatus for applying high voltage with high frequency according to claim 1, further comprising an impedance regulator which measures an impedance value of a circuit comprising the voltage transformer and the load, and regulates the impedance of the voltage transformer such that the impedance value measured becomes a predetermined value.

5. The apparatus for applying high voltage with high frequency according to claim 4, wherein the voltage transformer comprises:
a coupled inductor having a primary inductor and a secondary inductor, wherein the primary inductor is connected in parallel with the impedance matcher;
a capacitor connected in parallel with the secondary inductor of the coupled inductor to resonate with the secondary inductor of the coupled inductor; and
a variable capacitor connected in parallel with the capacitor to resonate with the secondary inductor of the coupled inductor, and connected with the impedance regulator.

6. The apparatus for applying high voltage with high frequency according to claim 5, wherein the impedance of the secondary inductor of the coupled inductor is identical to the impedance of a circuit comprising the capacitor and the variable capacitor connected in parallel with each other.

7. The apparatus for applying high voltage with high frequency according to claim 5, wherein the impedance regulator regulates the impedance of the variable capacitor such that the impedance of a circuit comprising the load, the capacitor, and the variable capacitor becomes a predetermined value.

8. The apparatus for applying high voltage with high frequency according to claim 1, wherein the impedance matcher comprises a circuit in which one or more resistors, one or more inductors, and one or more capacitors are connected in parallel.

9. The apparatus for applying high voltage with high frequency according to claim 1, further comprising a power amplifier connected between the power generator and the impedance matcher to amplify the electric power generated by the power generator and transmit the amplified power to the impedance matcher.

10. A method of applying high voltage with high frequency comprising the steps of:
generating electric power with predetermined frequency using a power generator;
transmitting the electric power while conducting an impedance-matching with the power generator; and
applying, to a load, the voltage of the electric power transmitted from the above step while amplifying the voltage.

11. The method of applying high voltage with high frequency according to claim 10, wherein the step of applying the voltage to the load comprises the steps of:
amplifying the voltage using a coupled inductor comprising a primary inductor and a secondary inductor; and
amplifying the impedance of the secondary side of the coupled inductor by the resonance between the secondary inductor of the coupled inductor and a capacitor.

12. The method of applying high voltage with high frequency according to claim 10, wherein before the step of generating the electric power with predetermined frequency, the method further comprises the steps of:
measuring the impedance of the load; and
regulating the impedance of the variable capacitor such that the impedance of a circuit comprising the load connected to a secondary inductor of a coupled inductor comprising a primary inductor and the secondary inductor, the capacitor, and the variable capacitor becomes a predetermined value,
and wherein the step of applying the voltage to the load comprises the steps of:
amplifying the voltage of the power transmitted using the coupled inductor; and
applying, to the load, the voltage amplified by a resonance between the secondary inductor of the coupled inductor, the capacitor and the variable capacitor.

13. The method of applying high voltage with high frequency according to claim 10, further comprising the step of, before the step of transmitting the electric power, amplifying the electric power generated in the step of generating electric power.
